(19) United States
(12) Patent Application Publication
(10) Pub. No.: US 2026/0324199 A1
(43) Pub. Date: Oct. 15, 2026

(54) DISPLAY PANEL, MANUFACTURING METHOD THEREFOR, AND DISPLAY APPARATUS

(71) Applicants: Beijing BOE Technology Development Co., Ltd., Beijing (CN); BOE Technology Group Co., Ltd., Beijing (CN)

(72) Inventors: Jianbo XIAN, Beijing (CN); Jingbo XU, Beijing (CN); Jingquan WANG, Beijing (CN); Juanjuan YOU, Beijing (CN); Donghui YU, Beijing (CN); Yong QIAO, Beijing (CN); Chunping LONG, Beijing (CN)

(21) Appl. No.: 18/834,780

(22) PCT Filed: Nov. 29, 2023
(86) PCT No.: PCT/CN2023/135084

§ 371 Date: Jul. 31, 2024

(51) Int. Cl. H10K 59/122; H10K 59/12; H10K 59/121

(52) U.S. Cl. CPC H10K 59/122; H10K 59/1201; H10K 59/1213

(57) ABSTRACT

The present disclosure provides a display panel, a manufacturing method thereof and a display apparatus, including: a base substrate; multiples pixel driving circuits on a side of the base substrate, and the pixel driving circuit including a drive transistor; multiples light-emitting devices on a side of the pixel driving circuits facing away from the base substrate, and the light-emitting device being electrically connected with a corresponding pixel driving circuit; a plurality of light-emitting enhancement structures between the pixel driving circuits and the light-emitting devices, and an orthographic projection of the light-emitting enhancement structure on the base substrate at least partially covers the orthographic projection of a corresponding light-emitting device on the base substrate, and the orthographic projection of the light-emitting enhancement structure on the base substrate does not overlap with an orthographic projection of a channel region of an active layer in the driving transistor on the base substrate.

### CROSS REFERENCE TO RELATED APPLICATIONS

The present disclosure is a national phase entry under 35 U.S. C § 371 of International Application No. PCT/CN2023/135084, filed Nov. 29, 2023, the entire content of which is incorporated herein by reference.

### TECHNICAL FIELD

The present disclosure relates to the field of a display technology, and particularly relates to a display panel, a manufacturing method therefor, and a display apparatus.

### BACKGROUND

In order to enhance the light extraction efficiency of Organic Light Emitting Diode (OLED) products, micro-lenses are often used to enhance the light emitting rate of the products. However, the setting of the micro-lens will lead to more light irradiation to other positions (e.g. an active layer) of the OLED products while enhancing the light emitting rate, thus affecting the performance of the OLED product.

### SUMMARY

The present disclosure provides a display panel, a display panel manufacturing method and a display apparatus. The specific solutions are as follows.

The display panel provided by the present disclosure includes a base substrate, a plurality of pixel driving circuits, a plurality of light-emitting devices and a plurality of light-emitting enhancement structures. The pixel driving circuits are on a side of the base substrate, and the pixel driving circuit includes a driving transistor. The light-emitting devices are on a side of the pixel driving circuits facing away of the base substrate, and the light-emitting device is electrically connected with a corresponding pixel driving circuit. The light-emitting enhancement structures are between the pixel driving circuits and the light emitting devices, an orthographic projection of the light-emitting enhancement structure on the base substrate at least partially covers an orthographic projection of a corresponding light-emitting device on the base substrate, and the orthographic projection of the light-emitting enhancement structure on the base substrate does not overlap with an orthographic projection of a channel region of an active layer in the driving transistor on the base substrate.

In a possible implementation, in the above-described display apparatus provided by the embodiments of the present disclosure, a distance between adjacent boundaries of orthographic projections, on the base substrate, of the light-emitting enhancement structure and the channel region of the active layer in the driving transistor is directly proportional to an area of the light-emitting device.

In a possible implementation, the above-described display apparatus provided by the embodiments of the present disclosure further includes a passivation layer between the pixel driving circuits and the light-emitting devices, a filtering layer between the passivation layer and the light-emitting devices, a planarization layer between the filtering layer and the light-emitting devices, a pixel definition layer on a side of the planarization layer facing away from the base substrate, and a metal wiring between the base substrate and the passivation layer and electrically connected with the pixel driving circuits. The pixel definition layer defines a plurality of sub-pixels, the plurality of light-emitting devices are disposed correspondingly within the plurality of the sub-pixels, the filtering layer includes a plurality of sub-filtering layers disposed correspondingly within the plurality of the sub-pixels, the planarization layer includes the light-emitting enhancement structures, and an orthographic projection of the pixel definition layer on the base substrate at least covers an orthographic projection of a portion of the metal wiring on the base substrate.

In a possible implementation, in the above-described display apparatus provided by the embodiments of the present disclosure, the light-emitting enhancement structure includes a plurality of indentations and a plurality of protrusions, and tilt angles of the protrusions are inversely proportional to a wavelength of light emitted from a corresponding sub-pixel.

In a possible implementation, in the above-described display apparatus provided by the embodiments of the present disclosure, the tilt angles of the protrusions corresponding to the sub-pixels each is 30°~60°, and a difference in tilt angles of protrusions corresponding to every two adjacent sub-pixels, from which light with different wavelengths is emitted, is 5°~10°.

In a possible implementation, in the above-described display apparatus provided by the embodiments of the present disclosure, the light-emitting enhancement structure includes a plurality of indentations and a plurality of protrusions, an area of orthographic projections of the protrusions on the base substrate is directly proportional to an area of the sub-filtering layer.

In a possible implementation, in the above-described display apparatus provided by the embodiments of the present disclosure, a shape of the orthographic projection of the protrusion on the base substrate is hexagonal, pentagonal or triangular.

In a possible implementation, in the above-described display apparatus provided by the embodiments of the present disclosure, an included angle between a central axis of orthographic projections of the protrusions on the base substrate and a vertical direction is directly proportional to a wavelength of light emitted from the corresponding sub-pixel.

In a possible implementation, in the above-described display apparatus provided by the embodiments of the present disclosure, the included angle corresponding to each of the sub-pixels is 3° to 18°, and a difference in included angles corresponding to every two adjacent sub-pixels, from which light with different wavelengths is emitted, is 3° to 5°.

In a possible implementation, in the above-described display apparatus provided by the embodiments of the present disclosure, at least one side, along an arrangement direction of the sub-pixels, of at least one light-emitting enhancement structure corresponding to a sub-pixel is provided with a vacant portion.

In a possible implementation, in the above-described display apparatus provided by the embodiments of the present disclosure, an area of the vacant portion is directly proportional to an area of the sub-filtering layer.

In a possible implementation, in the above-described display apparatus provided by the embodiments of the present disclosure, the light-emitting device includes: an anode between the planarization layer and the pixel definition layer, a light emitting layer on a side of the anode facing away from the base substrate, and a cathode on a side of the light emitting layer facing away from the base substrate; and each of the sub-pixels further includes a light-blocking structure between the anode and the light emitting layer. The light-blocking structure is arranged in contact with an inner wall of the pixel definition layer, and an orthographic projection of the light-blocking structure on the base substrate at least covers an orthographic projection of a portion of the light-emitting enhancement structure on the base substrate.

In a possible implementation, in the above-described display apparatus provided by the embodiments of the present disclosure, a structure of the light-emitting enhancement structure adjacent to the inner wall of the pixel definition layer is the indentation, and the orthographic projection of the light-blocking structure on the base substrate covers at least an orthographic projection of the lowest point of the indentation adjacent to the inner wall of the pixel definition layer on the base substrate.

In a possible implementation, in the above-described display apparatus provided by the embodiments of the present disclosure, the orthographic projection of the light-blocking structure on the base substrate at least covers an orthographic projection of half a width of the metal wiring on the base substrate.

In a possible implementation, in the above-described display apparatus provided by the embodiments of the present disclosure, the light-blocking structure is arranged in a same layer and made of a same material as the pixel definition layer.

In a possible implementation, in the above-described display apparatus provided by the embodiments of the present disclosure, a material of the pixel definition layer is a black light-absorbing material.

In a possible implementation, in the above-described display apparatus provided by the embodiments of the present disclosure, an area of the orthographic projection of the light-blocking structure on the base substrate is directly proportional to an area of the sub-filtering layer.

In a possible implementation, in the above-described display apparatus provided by the embodiments of the present disclosure, an anti-light crosstalk structure is provided between every adjacent sub-filtering layers, orthographic projections of the anti-light crosstalk structure, the light-blocking structure and the metal wiring on the base substrate have a first overlapping region, and a width of the first overlapping region is greater than half a width of the metal wiring.

In a possible implementation, in the above-described display apparatus provided by the embodiments of the present disclosure, a material of the anti-light crosstalk structure is a black matrix.

In a possible implementation, in the above-described display apparatus provided by the embodiments of the present disclosure, the anti-light crosstalk structure is a filter structure that is different in color from two sub-filtering layers adjacent to the anti-light crosstalk structure, and light emitted from the two sub-filtering layers and light emitted from the anti-light crosstalk structure are mixed as white light.

In a possible implementation, the above-described display apparatus provided by the embodiments of the present disclosure further includes an anti-reflection layer between the metal wiring and the passivation layer. An orthographic projection of the metal wiring on the base substrate is within an orthographic projection of the anti-reflection layer on the base substrate.

In a possible implementation, in the above-described display apparatus provided by the embodiments of the present disclosure, orthographic projections of the anti-reflection layer, the light-blocking structure and the metal wiring on the base substrate have a second overlapping region, and a width of the second overlapping region is greater than half a width of the metal wiring.

In a possible implementation, in the above-described display apparatus provided by the embodiments of the present disclosure, the pixel definition layer is provided with a first groove, and the first groove is filled with a light-absorbing structure.

In a possible implementation, in the above-described display apparatus provided by the embodiments of the present disclosure, a depth of the first groove is less than or equal to a height of the pixel definition layer.

In a possible implementation, in the above-described display apparatus provided by the embodiments of the present disclosure, the planarization layer is provided with a second groove arranged in correspondence with the first groove, the second groove penetrates through the planarization layer, and the light-absorbing structure extends into the second groove and is in contact with the anti-light crosstalk structure.

In a possible implementation, in the above-described display apparatus provided by the embodiments of the present disclosure, a material of the light-absorbing structure is a black organic resin.

In a possible implementation, in the above-described display apparatus provided by the embodiments of the present disclosure, a material of the light-absorbing structure is a ferrous metal, and a top part of the light-absorbing structure facing away from the base substrate is electrically connected with the cathode.

Accordingly, the embodiments of the present disclosure further provide a display apparatus, including the above-described display panel provided by the embodiments of the present disclosure.

Accordingly, the embodiments of the present disclosure further provide a display panel manufacturing method, for manufacturing the display panel provided by the embodiments of the present disclosure, and the manufacturing method includes:
forming the plurality of pixel driving circuits on the base substrate; where the pixel driving circuit includes the driving transistor;
forming the plurality of light-emitting enhancement structures on the side of the pixel driving circuits facing away from the base substrate; where the orthographic projection of the light-emitting enhancement structure on the base substrate does not overlap with the orthographic projection of the channel region of the active layer in the driving transistor on the base substrate;
forming the plurality of light-emitting devices on the side of the light-emitting enhancement structures facing away from the base substrate; where the orthographic projection of the light-emitting enhancement structure on the base substrate at least partially covers the orthographic projection of the corresponding light-emitting device on the base substrate.

### BRIEF DESCRIPTION OF FIGURES

FIG. 1 is a schematic diagram of a layout of a display panel provided by embodiments of the present disclosure.

FIG. 2 is a schematic diagram of an integration of cross-sections along directions CC′, EE′, and FF′ in FIG. 1.

FIG. 3 is a schematic diagram of another layout of the display panel provided by embodiments of the present disclosure.

FIG. 4 is a schematic structural diagram of a pixel driving circuit of 3T1C.

FIG. 5 is a schematic structural diagram of a pixel driving circuit of 2T1C.

FIG. 6 is a schematic structural diagram of a pixel driving circuit of 7T1C.

FIG. 7 is a schematic diagram separately illustrating a structure of a light-emitting enhancement structure above each sub-filtering layer in FIG. 2.

FIG. 8 is a schematic diagram of sizes of areas of orthographic projections of protrusions corresponding to sub-pixels of different areas.

FIG. 9 is a schematic diagram of another cross-section of a display panel provided by embodiments of the present disclosure.

FIG. 10 is a schematic diagram of yet another cross-section of a display panel provided by embodiments of the present disclosure.

FIG. 11 is a schematic diagram of yet another cross-section of a display panel provided by embodiments of the present disclosure.

FIG. 12 is a schematic diagram of yet another cross-section of a display panel provided by embodiments of the present disclosure.

FIG. 13 is a schematic diagram of yet another cross-section of a display panel provided by embodiments of the present disclosure.

FIG. 14 is a schematic diagram of yet another cross-section of a display panel provided by embodiments of the present disclosure.

FIG. 15 is a schematic diagram of yet another cross-section of a display panel provided by embodiments of the present disclosure.

FIG. 16 is a schematic diagram of yet another cross-section of a display panel provided by embodiments of the present disclosure.

FIG. 17 is a schematic diagram of yet another cross-section of a display panel provided by embodiments of the present disclosure.

FIG. 18 is a schematic diagram of yet another cross-section of a display panel provided by embodiments of the present disclosure.

FIG. 19 is a schematic flow chart of a display panel manufacturing method provided by embodiments of the present disclosure.

FIG. 20A-FIG. 20D are schematic sectional views of the display panel provided by embodiments of the present disclosure after performing each step, respectively.

FIG. 21 is a schematic diagram of a display apparatus provided by embodiments of the present disclosure.

### DETAILED DESCRIPTION

In order to make objectives, technical solutions and advantages of the embodiments of the present disclosure clearer, the technical solutions of the embodiments of the present disclosure are described clearly and completely below with reference to the drawings of the embodiments of the present disclosure. Apparently, the described embodiments are some, not all, of the embodiments of the present disclosure. The embodiments in the present disclosure and the features in the embodiments may be combined with each other without conflict. Based on the described embodiments of the present disclosure, all other embodiments obtained by those of ordinary skill in the art without inventive efforts fall within the protection scope of the present disclosure.

Unless otherwise indicated, the technical or scientific terms used in the present disclosure shall have the usual meanings understood by a person of ordinary skill in the art to which the present disclosure belongs. The word “including” or “containing” and the like, means that an element or item preceding the word covers an element or item listed after the word and the equivalent thereof, without excluding other elements or items. The word “connection” or “coupling” and the like is not restricted to physical or mechanical connection, but may include electrical connection, whether direct or indirect. The terms “inside”, “outside”, “up”, “down”, etc., are used to indicate relative positional relationships, and when the absolute position of the described object changes, the relative positional relationship may change accordingly.

It should be noted that the sizes and shapes of the figures in the drawings do not reflect true proportions and are only intended to illustrate the present disclosure. And the same or similar reference numbers throughout represent the same or similar elements or elements with the same or similar functions.

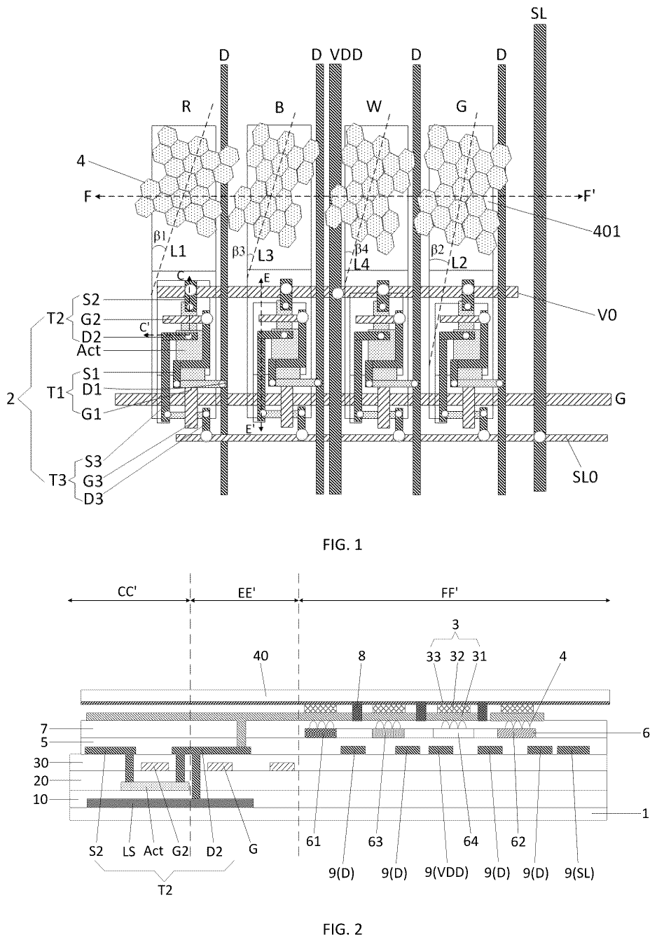

Embodiments of the present disclosure provide a display panel as shown in FIG. 1 and FIG. 2. FIG. 1 shows a schematic diagram of a layout of the display panel, and FIG. 2 shows a schematic diagram of an integration of cross-sections along the directions CC′, EE′, and FF′ in FIG. 1. The display panel includes a base substrate 1, a plurality of pixel driving circuits 2, a plurality of light-emitting devices 3, and a plurality of light-emitting enhancement structures 4.

The plurality of pixel driving circuits 2 are on a side of the base substrate 1, and the pixel driving circuit 2 includes a driving transistor T2.

The plurality of light-emitting devices 3 are on a side of the pixel driving circuits 2 facing away from the base substrate 1, the light emitting device 3 is electrically connected with a corresponding pixel driving circuit 2.

The plurality of light-emitting enhancement structures 4 are between the pixel driving circuits 2 and the light-emitting devices 3, an orthographic projection of the light-emitting enhancement structure 4 on the base substrate 1 at least partially covers an orthographic projection of a corresponding light-emitting device 3 on the base substrate 1, and the orthographic projection of the light-emitting enhancement structures 4 on the base substrate 1 does not overlap with an orthographic projection of the transistor included in the pixel driving circuit 2 on the base substrate 1. For example, the orthographic projection of the light-emitting enhancement structures 4 on the base substrate 1 does not overlap with an orthographic projection of a channel region of an active layer Act in the driving transistor T2 of the pixel driving circuit 2 on the base substrate 1, and the channel region includes an overlap region between a gate G2 of the driving transistor T2 and the active layer Act.

In the above-described display panel provided by embodiments of the present disclosure, the light emitting rate of the display panel can be improved by providing a light-emitting enhancement structure whose orthographic projection at least partially covers the light-emitting device; since the channel region of the active layer (e.g., the channel region of an oxide active layer) in the transistor (e.g., driving transistor) is greatly affected by the light, the light-emitting enhancement structure should be kept away from the channel region as much as possible. In the present disclosure, the orthographic projection of the light-emitting enhancement structure on the base substrate is set to not overlap with the orthographic projection of the channel region of the active layer of the transistor (e.g., driving transistor) on the base substrate, so that light can be avoided from irradiating the channel region of the driving transistor while improving the light emitting rate of the products, thereby ensuring that the channel region of the driving transistor is not affected by the light and improving the performance of the pixel driving circuit.

Optionally, as shown in FIG. 1, the base substrate 1 may include a plurality of sub-pixels, such as a red sub-pixel (R), a green sub-pixel (G), a blue sub-pixel (B), and a white sub-pixel (W), and of course, is not limited thereto. For example, the base substrate 1 may include a plurality of sub-pixels, such as a red sub-pixel (R), a green sub-pixel (G), and a blue sub-pixel (B).

In some embodiments, generally each sub-pixel correspondingly includes a pixel driving circuit and a light-emitting device, and the pixel driving circuit driving the light-emitting device to emit light.

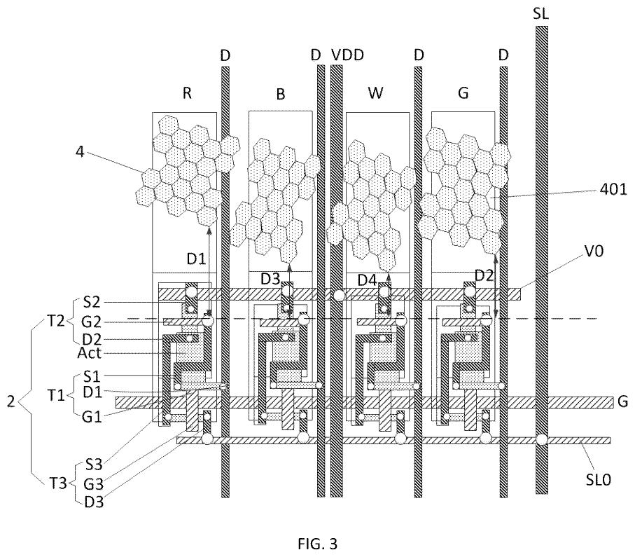

In some embodiments, in the above-described display panel provided by embodiments of the present disclosure, as shown in FIG. 3, a distance (D1, D2, D3, D4) between adjacent boundaries of orthographic projections of the light-emitting enhancement structure 4 and the channel region of the active layer Act in the driving transistor T2 on the base substrate 1 is directly proportional to an area of the light-emitting device 3. Optionally, for example, an area of the light-emitting device 3 within the red sub-pixel (R), an area of the light-emitting device 3 within the green sub-pixel (G), an area of the light-emitting device 3 within the blue sub-pixel (B), and an area of the light-emitting device 3 within the white sub-pixel (W) decreases in order, the distance between a boundary of the orthographic projection, on the base substrate, of the light-emitting enhancement structure 4 within the red sub-pixel (R) and an adjacent boundary of the orthographic projection, on the base substrate 1, of the channel region of the active layer Act is D1, the distance between a boundary of the orthographic projection, on the base substrate, of the light-emitting enhancement structure 4 within the green sub-pixel (G) and an adjacent boundary of the orthographic projection, on the base substrate, of the channel region of the active layer Act is D2, the distance between a boundary of the orthographic projection, on the base substrate, of the light-emitting enhancement structure 4 with the blue sub-pixel (B) and an adjacent boundary of the orthographic projection, on the base substrate, of the channel region of the active layer Act is D3, and the distance between a boundary of the orthographic projection, on the base substrate, of the light-emitting enhancement structure 4 within the white sub-pixel (W) and an adjacent boundary of the orthographic projection, on the base substrate, of the channel region of the active layer Act is D4, so that D1>D2>D3>D4. That is, the larger the area of the light-emitting device 3 is, the farther the light-emitting enhancement structure 4 is from the channel region of the active layer Act, because the larger the area of the light-emitting device 3 is, the larger the area of the light-emitting enhancement structure 4 is, and the larger the coverage area of the reflected light is. In order to avoid the reflected light from affecting the channel region of the active layer Act, the larger the area of the light-emitting device 3, the corresponding light-emitting enhancement structure 4 should be farther away from the channel region of the active layer Act, so as to protect the channel region of the active layer Act from being affected by the light.

In some embodiments, as shown in FIG. 3, in order to reduce the complexity of the fabrication process, the orthographic projection of the light-emitting enhancement structure 4 on the base substrate 1 may not overlap with the orthographic projection of the active layer Act in the driving transistor T2 on the base substrate 1. Furthermore, the orthographic projection of the light-emitting enhancement structure 4 on the base substrate 1 may not overlap with an orthographic projection of an entire pixel driving circuit 2 on the base substrate 1. In this way, the light reflected from the light-emitting enhancement structure 4 can be further prevented from irradiating the channel region of the active layer Act.

It should be noted that the embodiments of the present disclosure are based on the example that the base substrate 1 is divided into a red sub-pixel (R), a green sub-pixel (G), a blue sub-pixel (B), and a white sub-pixel (W), but of course it is also possible to include only the red sub-pixel (R), the green sub-pixel (G), and the blue sub-pixel (B), which is selected according to the need for display.

It should be noted that the embodiments of the present disclosure are illustrated with an example that the area of the light-emitting device 3 within the red sub-pixel (R), the area of the light-emitting device 3 within the green sub-pixel (G), the area of the light-emitting device 3 within the blue sub-pixel (B), and the area of the light-emitting device 3 within the white sub-pixel (W) are sequentially reduced, of course, which is not limited to this, and the size of the area of the light-emitting device 3 corresponding to each of the sub-pixels can be designed according to the need.

In some embodiments, as shown in FIG. 2, the above-described display panel provided by embodiments of the present disclosure further includes: a passivation layer 5 disposed between the pixel driving circuit 2 and the light-emitting device 3, a filtering layer 6 disposed between the passivation layer 5 and the light-emitting device 3, a planarization layer 7 disposed between the filtering layer 6 and the light-emitting device 3, a pixel definition layer 8 disposed on a side of the planarization layer 7 facing away the base substrate 1, and a metal wiring 9 arranged between the base substrate 1 and the passivation layer 5 and electrically connected with the pixel driving circuit 2, for example, the metal wiring 9 includes a gate line G, a data signal line D, a fixed level signal line (e.g., a high voltage line VDD), a fixed level signal connecting line V0, a sense line SL, a sense signal connecting line SL0, etc. For example, the pixel driving circuits 2 corresponding to a plurality of sub-pixels (R, G, B, W) are connected with the fixed level signal line (e.g., a high voltage line VDD) through the same one fixed level signal connecting line V0; the pixel driving circuits 2 corresponding to the plurality of sub-pixels (R, G, B, W) are connected with the sensing line SL through the same one sense signal connecting line SL0.

Herein, the pixel definition layer 8 defines a plurality of sub-pixels (R, G, B, W), a plurality of light-emitting devices 3 are correspondingly disposed within the plurality of sub-pixels (R, G, B, W), the filtering layer 6 includes a plurality of sub-filtering layers (61, 62, 63, and 64) correspondingly arranged within the plurality of sub-pixels (R, G, B, W), and the planarization layer 7 includes the light-emitting enhancement structures 4 (i.e., the light-emitting enhancement structures are made using the planarization layer 7, which can reduce the cost and does not increase the thickness of the display panel), and an orthographic projection of the pixel definition layer 8 on the base substrate 1 at least covers an orthographic projection of a portion of a region of the metal wiring 9 on the base substrate 1, such that setting the metal wiring 9 below the pixel definition layer 8 can avoid the metal wiring 9 from occupying the space of the sub-pixels, thereby increasing an aperture ratio of pixels.

In embodiments of the present disclosure, the display panel may specifically be an OLED display panel using a bottom-emitting structure.

In some embodiments, as shown in FIG. 3, a width of a fixed level signal line (e.g., a high voltage line VDD) is usually larger than a width of a data signal line (e.g., data), and an overlapping area of the light-emitting enhancement structure 4 and the fixed level signal line (e.g., the high voltage line VDD) is larger than an overlapping area of the light-emitting enhancement structure 4 and the data signal line (e.g., data), and such a design is favorable for improving the utilization of light at the edge region of the sub-pixel.

In the embodiments of the present disclosure, the plurality of sub-filtering layers (61, 62, 63, and 64) may include a red light sub-filtering layer 61, a green light sub-filtering layer 62, a blue light sub-filtering layer 63, and a white light sub-filtering layer 64, and the plurality of sub-filtering layers are provided at intervals. It is understood that the red light sub-filtering layer 61, the green light sub-filtering layer 62, the blue light sub-filtering layer 63, and the white light sub-filtering layer 64 are used for the passage of red light, green light, blue light, and white light, respectively, so as to form the three primary colors of the light-emitting display of the display panel. Of course, the white light sub-filtering layer 64 may also be provided without anything or with a transparent resin layer to increase the light transmittance.

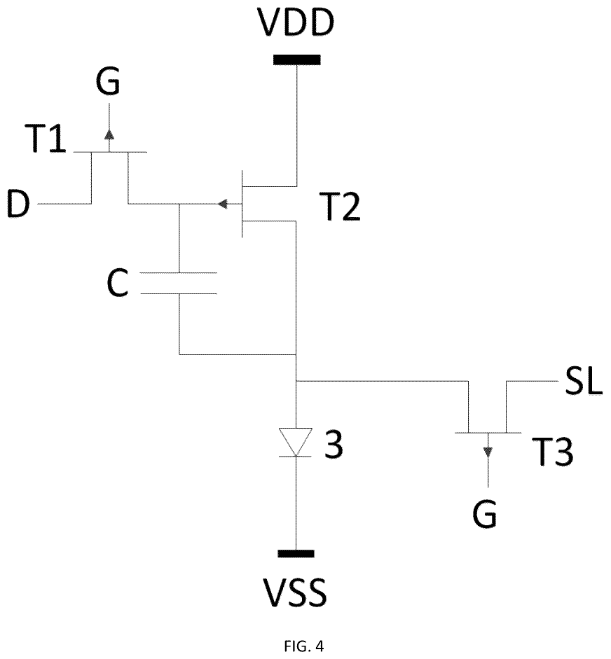

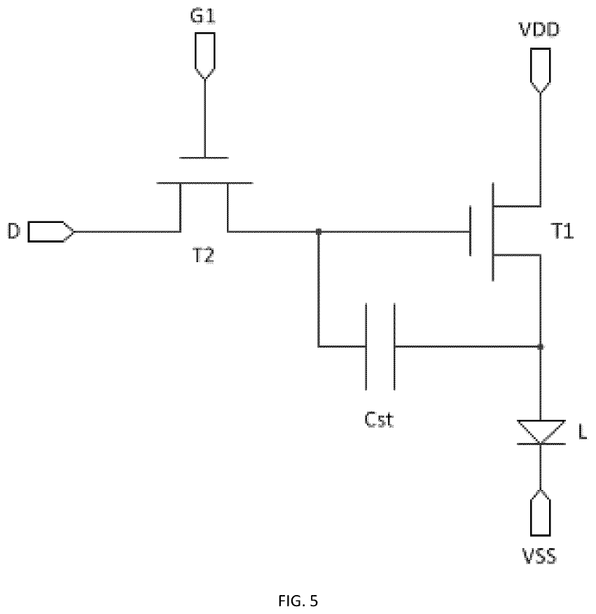

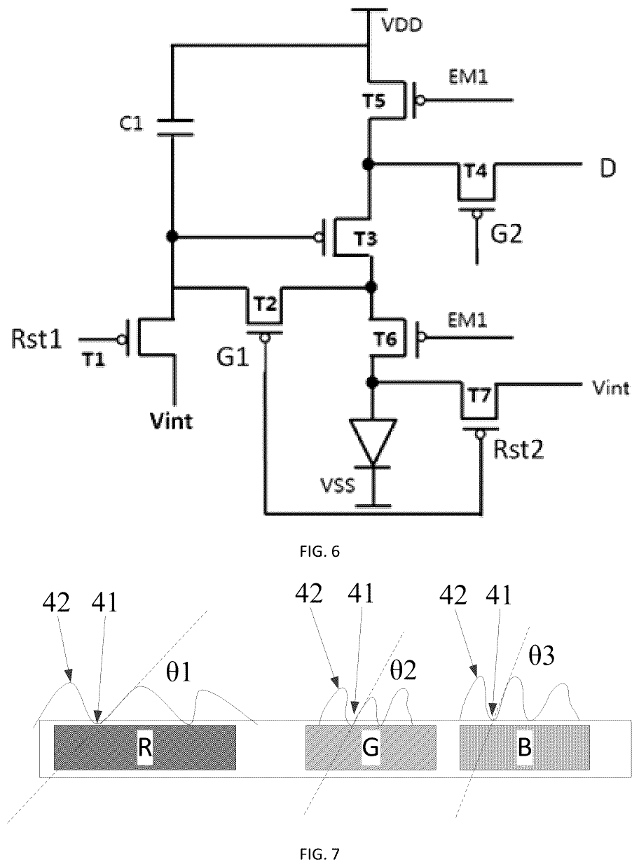

In embodiments of the present disclosure, as shown in FIG. 1-FIG. 3, the pixel driving circuit 2 may be of a structure including 3 transistors and 1 capacitor (3T1C), and the equivalent circuit structure of 3T1C is shown in FIG. 4. Optionally, the pixel driving circuit may adopt various other structures, for example, the pixel driving circuit may be of a structure including 2 transistors and 1 capacitor (2T1C) as shown in FIG. 5, herein T1 is a driving transistor; or the pixel driving circuit may be of a structure including 7 transistors and 1 capacitor (7T1C) as shown in FIG. 6, herein T3 is a driving transistor; and the like. The pixel driving circuit generally includes a driving thin-film transistor and the remaining switching thin-film transistors and storage capacitors.

As shown in FIG. 1-FIG. 4, the pixel driving circuit 2 includes a switching transistor T1, a driving transistor T2, a sense transistor T3, and a capacitor C. A gate G1 of the switching transistor T1 is electrically connected with the gate line G, a first electrode S1 of the switching transistor is electrically connected with the data signal line D, a second electrode D1 of the switching transistor T1 is electrically connected with a gate G2 of the driving transistor T2. A first electrode S2 of the driving transistor T2 is electrically connected with a high voltage line VDD (e.g., the first electrode S2 of the driving transistor T2 is electrically connected with the high voltage line VDD through a fixed level signal connecting line V0), a second electrode D2 of the driving transistor T2 is electrically connected with an anode of the light-emitting device 3. a gate of the sense transistor T3 is electrically connected with the gate line G, and a first electrode of the sense transistor T3 is electrically connected with the sense line SL (e.g., the first electrode of the sense transistor T3 is electrically connected with the sense line SL through the sense signal connecting line SL0), a second electrode of the sense transistor T3 is electrically connected with the anode of the light-emitting device 3. A cathode of the light-emitting device 3 is electrically connected with a low voltage line VSS, an end of the capacitor C is electrically connected with the gate of the drive transistor T2, and the other end of the capacitor C is electrically connected with the anode of the light-emitting device 3.

In some embodiments, as shown in FIG. 2, the light-emitting device 3 includes: an anode 31 arranged between the planarization layer 7 and the pixel definition layer 8, a light emitting layer 32 arranged on a side of the anode 31 facing away from the base substrate 1, and a cathode 33 arranged on a side of the light emitting layer 32 facing away from the base substrate 1. Specifically, holes of the anode 31 and electrons of the cathode 33 are injected into the light emitting layer 32 for composite emission.

In some embodiments, as shown in FIG. 1 and FIG. 2, in at least one sub-pixel, the display panel further includes: a light-shielding layer LS disposed between the base substrate 1 and the active layer Act, a buffer layer 10 disposed between the light-shielding layer LS and the active layer Act, a gate insulating layer 20 arranged between the active layer Act and the gate, an interlayer insulating layer 30 arranged between the gate and the source-drain electrode, and an encapsulation layer 40 arranged on a side of the cathode 33 facing away from the base substrate 1. Among them, the encapsulation layer 40 may adopt a thin film encapsulation, for example, the encapsulation layer 40 may include a first inorganic layer, an organic layer, and a second inorganic layer which are stacked, and the encapsulation layer 40 is used to encapsulate the light-emitting device 3, to prevent the external water vapor from eroding the light-emitting device 3. Of course, other encapsulation methods, such as face encapsulation, can be used.

In some embodiments, as shown in FIG. 1 and FIG. 2, the anode 31 of the light-emitting device 3 is at least partially overlapped with a corresponding light-shielding layer LS and a channel region of an active layer of a corresponding driving transistor T2, and there is no overlap region between the sub-filtering layer of the sub-pixel and the corresponding light-shielding layer LS. An area of the anode 31 of the light-emitting device 3 may be larger than an area of the corresponding sub-filtering layer.

It should be noted that the principle of driving the light-emitting device 3 to emit light by the pixel driving circuit shown in FIG. 4 may be the same as that of the prior art, and will not be described in detail herein.

In some embodiments, in the above-described display panel provided by embodiments of the present disclosure, as shown in FIG. 2 and FIG. 7, FIG. 7 separately illustrates the light-emitting enhancement structure 4 above each sub-filtering layer (61, 62, and 63) in FIG. 2, and the light-emitting enhancement structure 4 may include a plurality of indentations 41 and a plurality of protrusions 42, and since there are differences in the convergence effect of different light-emitting enhancement structures 4 for light with different wavelengths, in order to improve the light mixing effect, tilt angles of the protrusions 42 of the light-emitting enhancement structure 4 may be set to achieve a better light emission efficiency and a better light mixing effect, for example, the tilt angles of the protrusions 42 are inversely proportional a the wavelength of light emitted from a corresponding sub-pixel. Specifically, a wavelength of a light emitted from the red sub-pixel (R) is greater than a wavelength of a light emitted from the green sub-pixel (G), and the wavelength of the light emitted from the green sub-pixel (G) is greater than a wavelength of a light emitted from the blue sub-pixel (B). Therefore, the relationship between a tilt angle 01 of the light-emitting enhancement structure 4 corresponding to the red sub-pixel (R), a tilt angle θ2 of the light-emitting enhancement structure 4 corresponding to the green sub-pixel (G) and a tilt angle θ3 of the light-emitting enhancement structure 4 corresponding to the blue sub-pixel (B) is: θ1×θ2×θ3.

Optionally, as shown in FIG. 7, the tilt angles θ1 of the protrusions 42 corresponding to the red sub-pixel (R) may be 30° to 60°, the tilt angles θ2 of the protrusions 42 corresponding to the green sub-pixel (G) may be 30° to 60°, and the tilt angles ν3 of the protrusions 42 corresponding to the blue sub-pixel (B) may be 30° to 60°.

Optionally, as shown in FIG. 7, a difference in tilt angles of the protrusions corresponding to every two adjacent sub-pixels, from which light with different wavelengths is emitted, may be 5° to 10°, which is favorable for light convergence. For example, a difference between the tilt angle θ1 of the light-emitting enhancement structure 4 corresponding to the red sub-pixel (R) and the tilt angle θ2 of the light-emitting enhancement structure 4 corresponding to the green sub-pixel (G) is 5° to 10°, and a difference between the tilt angle θ2 of the light-emitting enhancement structure 4 corresponding to the green sub-pixel (G) and the tilt angle θ3 of the light-emitting enhancement structure 4 corresponding to the blue sub-pixel (B) is 5° to 10°. Optionally, the difference between θ1 and θ2 and the difference between θ2 and θ3 may be the same or different.

In some embodiments, in the above-described display panel provided by embodiments of the present disclosure, as shown in FIG. 2 and FIG. 8, the light-emitting enhancement structure 4 includes a plurality of indentations 41 and a plurality of protrusions 42, and in order to improve the light gathering effect of the light-emitting enhancement structure 4, an area of orthographic projections of the projections 42 on the base substrate 1 may be directly proportional to an area of the sub-filtering layer. Optionally, for example, an area of the red light sub-filtering layer 61, an area of the green light sub-filtering layer 62, and an area of the blue light sub-filtering layer 63 decreases sequentially, the area of the orthographic projections of the protrusions 42 corresponding to the red sub-pixel (R) on the base substrate 1 is S11, the area of the orthographic projections of the protrusions 42 corresponding to the green sub-pixel (G) on the base substrate 1 is S12, the area of the orthographic projections of the protrusions 42 corresponding to the blue sub-pixel (B) on the base substrate 1 is S13, such that S11>S12>S13, i.e., the larger the area of the sub-filtering layer, the larger the area of the orthographic projections of the protrusions 42 on the base substrate 1.

Optionally, as shown in FIG. 8, a shape of the orthographic projection of the protrusion 42 on the base substrate 1 is hexagonal; of course, a shape of the orthographic projection of the protrusion 42 on the base substrate 1 may also be pentagonal or triangular, and the present disclosure is not limited thereto.

In some embodiments, in order to make the edges of adjacent sub-pixels leak light evenly and improve uniformity, as shown in FIG. 1, the light-emitting enhancement structure 4 can be inclined in the above display panel provided by the present embodiments. For example, an included angle between a central axis L1 of the orthographic projections of the protrusions 42 on the base substrate 1 and the vertical direction (such as the column direction) is directly proportional to a wavelength of the light emitted from the corresponding sub-pixel. Specifically, for example, an included angle between the central axis L1 of the orthographic projections of the protrusions 42 corresponding to the red sub-pixel (R) on the base substrate 1 and the vertical direction is β1, an included angle between the central axis L2 of the orthographic projections of the protrusions 42 corresponding to the green sub-pixel (G) on the base substrate 1 and the vertical direction is β2, an included angle between the central axis L3 of the orthographic projections of the protrusions 42 corresponding to the blue sub-pixel (B) on the base substrate 1 and the vertical direction is 33, and an included angle between the central axis L4 of the orthographic projections of the protrusions 42 corresponding to the white sub-pixel (W) on the base substrate 1 and the vertical direction is β4, and thus β1>β2>β3>β4.

Optionally, as shown in FIG. 1, the included angle β1 corresponding to the red sub-pixel (R) may be 3°~18, the included angle β2 corresponding to the green sub-pixel (G) may be 3°~18, the included angle β3 corresponding to the blue sub-pixel (B) may be 3°~18, and the included angle β4 corresponding to the white sub-pixel (W) may be 3°~18.

Optionally, as shown in FIG. 1, a difference in included angles corresponding to every two adjacent two sub-pixels, from which light with different wavelengths is emitted, may be 3° to 5°. For example, a difference between the included angle β1 corresponding to the red sub-pixel (R) and the included angle β2 corresponding to the green sub-pixel (G) may be 3°~5°, a difference between the included angle β2 corresponding to the green sub-pixel (G) and the included angle β3 corresponding to the blue sub-pixel (B) may be 3°~5°, and a difference between the included angle β3 corresponding to the blue sub-pixel (B) and the included angle β4 corresponding to the white sub-pixel (W) may be 3°~5°.

Optionally, the difference between β1 and β2, the difference between β2 and β3, and the difference between β3 and β4 may be the same or different.

It is to be understood that the light-emitting enhancement structure provided by embodiments of the present disclosure may be a micro/nano optical element consisting, such as of many tiny prisms or lenses, usually arranged in a regular array. These prisms or lenses can focus or disperse the light, thereby realizing the control and adjustment of the light to enhance the light emitting rate of the OLED display product.

Optionally, the light-emitting enhancement structure provided by embodiments of the present disclosure may be a micro-lenses array fabricated using a planarization layer. Optionally, the micro-lenses array may be processed and molded by an exposure development process or a dry etching process.

It is to be understood that exposure development is a photolithographic process in which the basic principle of the process is to cover the surface of the light-sensitive material with a photomask, and then expose the photomask to ultraviolet or visible light, so that a pattern on the photomask is projected onto the surface of the light-sensitive material to form an exposed region and an unexposed region of the pattern. Afterwards, the light-sensitive material is subjected to a development process, so that the light-sensitive material in the unexposed region is dissolved away, while the light-sensitive material in the exposed region is retained to form the desired micro-lenses array. The dry etching process is a type of micro-nanofabrication process, and the basic principle of the process is to utilize a high-energy ion beam or plasma to process the surface of the material to form a desired pattern or structure. Embodiments of the present disclosure may specifically be processed to form micro-lenses arrays using a physical dry etching process or a chemical dry etching process.

In some embodiments, in the above-described display panel provided by embodiments of the present disclosure, as shown in FIG. 1 and FIG. 3, at least one side, along an arrangement direction of the sub-pixels (e.g., the row direction), of at least one light-emitting enhancement structure 4 corresponding to a sub-pixel is provided with a vacancy portion 401. On the one hand, the design of the vacancy portion 401 can be used to make an alignment mark of the light-emitting enhancement structure 4 and to identify the alignment of the light-emitting enhancement structure 4; on the other hand, the tilt angles of the light-emitting enhancement structures 4 corresponding to different sub-pixels can be compared due to the design of the vacancy portion 401.

Optionally, as shown in FIG. 1-FIG. 3, an area of the vacancy portion 401 is directly proportional to the area of the sub-filtering layer, i.e., the larger the area of the sub-filtering layer, the larger the area of the vacancy portion 401. For example, the area of the red light sub-filtering layer 61>the area of the green light sub-filtering layer 62>the area of the blue light sub-filtering layer 63, such that the area of the vacancy portion 401 corresponding to the red sub-pixel (R)>the area of the vacancy portion 401 corresponding to the green sub-pixel (G)>the area of the vacancy portion 401 corresponding to the blue sub-pixel (B).

Optionally, the vacancy portion 401 can accommodate 4-10 hexagons.

Optionally, as shown in FIG. 1 and FIG. 3, the vacancy portions 401 corresponding to respective sub-pixels may not be on the same level. Such a design facilitates the respective independent alignment of sub-pixels of different colors.

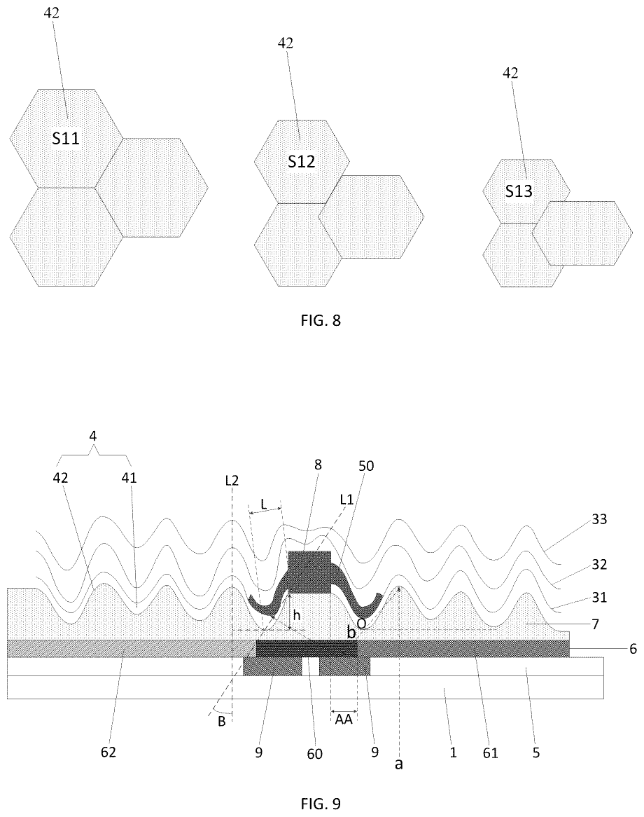

In some embodiments, a portion of the light emitted by the light-emitting device or the ambient light will be incident on the surface of the metal wiring after being reflected by the micro-lenses, and will be reflected again to other adjacent sub-pixels via the metal wiring, which will result in the phenomenon of light leakage and cause the phenomenon of color crosstalk or crosstalk of adjacent sub-pixels. In order to improve the phenomenon of light leakage of the display panel, in the above-described display panel provided by the presently disclosed embodiments, as shown in FIG. 9, each sub-pixel further includes a light-blocking structure 50 between the anode 31 and the light-emitting layer 32, the light-blocking structure 50 is provided in contact with an inner wall of the pixel definition layer 8, and an orthographic projection of the light-blocking structure 50 on the base substrate 1 at least overlaps an orthographic projection of a portion of the light-emitting enhancement structure 4 on the base substrate 1. In the present disclosure, by adding the light-blocking structure 50 covering at least a portion of the light-emitting enhancement structure at a corresponding position of the metal wiring 9 of the adjacent sub-pixels, the light-blocking structure 50 is located in a path of the light reflected from a light-emitting enhancement structure 4 close to the other sub-pixels, and blocks the light from exiting to the metal wiring below, and thus cannot be reflected to the other sub-pixels, avoiding crosstalk of the light from the adjacent sub-pixels, and thus avoiding the phenomenon of light leakage in the display panel. For example, after the light emitted by the light-emitting device 3 of the red sub-pixel (R) is scattered by the light-emitting enhancement structure 4, a portion of the light directly enters the red light sub-filtering layer 61 provided directly opposite the red sub-pixel, and then emits light with a corresponding color after being filtered by the red light sub-filtering layer 61, while another portion of the light easily enters other sub-filtering layers (e.g., a green light sub-filtering layer 62) adjacent to the red light sub-filtering layer 61, or is incident on the metal wiring 9 and then is reflected back to the adjacent green light sub-filtering layer 62. The light-blocking structure 50 provided in the present disclosure can block another portion of the above-described light from entering the adjacent green light sub-filtering layer 62, and thus avoid crosstalk of light from adjacent sub-pixels.

In some embodiments, as shown in FIG. 1 and FIG. 3, there is no overlap between the light-emitting enhancement structure 4 and the fixed level signal connecting line V0 close to the driving transistor T2, so as to reduce the light that is reflected into a region where the driving transistor is located through the fixed level signal connecting line V0. Optionally, a distance of the light-emitting enhancement structure 4 from the fixed level signal connecting line V0 may be directly proportional to an area of a corresponding light-emitting device 3. Because the larger the area of the light emitting device 3, the larger the area of the light-emitting enhancement structure 4 is, and the larger the range of the area covered by the reflected light, in order to avoid the reflected light from affecting the channel region of the active layer Act, the larger the area of the light emitting device 3 is, the corresponding light-emitting enhancement structure 4 should be farther away from the fixed level signal connecting line V0, to protect the channel region of the active layer Act from being affected by the light.

In some embodiments, in the above-described display panel provided by embodiments of the present disclosure, as shown in FIG. 9, a structure of the light-emitting enhancement structure 4 adjacent to the inner wall of the pixel definition layer 8 is the indentation 41, and the orthographic projection of the light-blocking structure 50 on the base substrate 1 covers at least an orthographic projection of the lowest point of the indentation 41 adjacent to the inner wall of the pixel definition layer 8 on the base substrate 1. Specifically, for example, after the ambient light a passes through the protrusion 42, the reflected light b thereof must at least exceed the lowest point O of the indentation 41 before it may enter other adjacent sub-pixels, and therefore it is more desirable that the light-blocking structure 50 should cover the point O, that is, an end of the light-blocking structure 50 is arranged in contact with the inner wall of the pixel definition layer 8, and the other end of the light-blocking structure 50 extends at least to the position of the lowest point O of the indentation 41 adjacent to the inner wall of the pixel definition layer 8.

Optionally, as shown in FIG. 9, the orthographic projection of the light-blocking structure 50 on the base substrate 1 may cover orthographic projections of an indentation 41 and a protrusion 42 adjacent to the inner wall of the pixel definition layer 8 on the base substrate 1. This can further block the light reflected from the light-emitting enhancement structure 4 and avoid crosstalk of light from adjacent sub-pixels.

In some embodiments, in order to block the light reflected by the metal wiring into the adjacent sub-pixels, in the above-described display panel provided by embodiments of the present disclosure, as shown in FIG. 9, the pixel definition layer 8 is overlapped with two metal wirings 9, and the orthographic projection of the light-blocking structure 50 on the base substrate 1 at least covers an orthographic projection of half a width of the metal wiring 9 on the base substrate 1. This blocks light reflected from a large portion of the metal wiring 9 to adjacent sub-pixels.

Optionally, the orthographic projection of the light-blocking structure 50 on the base substrate 1 may cover the orthographic projection of the entire metal wiring 9 on the base substrate 1, so that more light is blocked.

Optionally, as shown in FIG. 9, a length L of the light-blocking structure 50 satisfies: L≥h/CosB, herein L is the length of the light-blocking structure 50 in a direction extending from the pixel definition layer 8 to the light-emitting enhancement structure 4, e.g., L is the length of the light-blocking structure 50 that extends from a point where the light-blocking structure 50 contacts with the anode 31 as a starting point to the light-emitting enhancement structure 4; the angle B is an angle formed by a line L1 connecting a highest point of the protrusion 42 with the lowest point O of the indentation 41 close to the light-blocking structure 50 and the vertical line L2 (perpendicular to the base substrate) of the highest point of the protrusion 42; and h is a height of the highest point of the protrusion 42 to a horizontal line (parallel to the base substrate) where the lowest point O of the indentation 41 is located.

In some embodiments, in the above-described display panel provided by embodiments of the present disclosure, the light-blocking structure 50 and the pixel definition layer 8 may be arranged in the same layer and made of the same material, as shown in FIG. 9. This can simplify the fabrication process, such as a black light-absorbing material is used to fabricate the pixel definition layer 8 and the light-blocking structure 50 to ensure that the reflected light from the light-emitting enhancement structure 4 is absorbed as much as possible.

In some embodiments, in the above-described display panel provided by embodiments of the present disclosure, as shown in FIG. 9, a thickness of the light-blocking structure 50 is smaller than a thickness of the pixel definition layer 8, e.g., the thickness of the light-blocking structure 50 is ⅕ to 1/100 of the thickness of the pixel definition layer 8, and if the thickness of the light-blocking structure 50 is too large, it is easy to cause the distance between the anode 31 and the light-emitting layer 32 to be too large, which makes the anode 31 and the light-emitting layer 32 in poor contact, thereby affecting the light-emitting effect of the light-emitting layer 32; and it is also easy to make the phenomenon of fracture when depositing the light-emitting layer 32.

In some embodiments, in the above-described display panel provided by embodiments of the present disclosure, as shown in FIG. 9, shapes of the anode 31, the light-emitting layer 32, and the cathode 33 are consistent with a shape of the light-emitting enhancement structure 4 (i.e., set up with the shape). On the one hand, the fabrication process can be simplified, and on the other hand, it is also favorable to the light emitted from the light-emitting enhancement structure 4. The light-emitting layers 32 of adjacent sub-pixels may be set connected or disconnected from each other, and the cathodes 33 of adjacent sub-pixels may be integrally set on a whole surface.

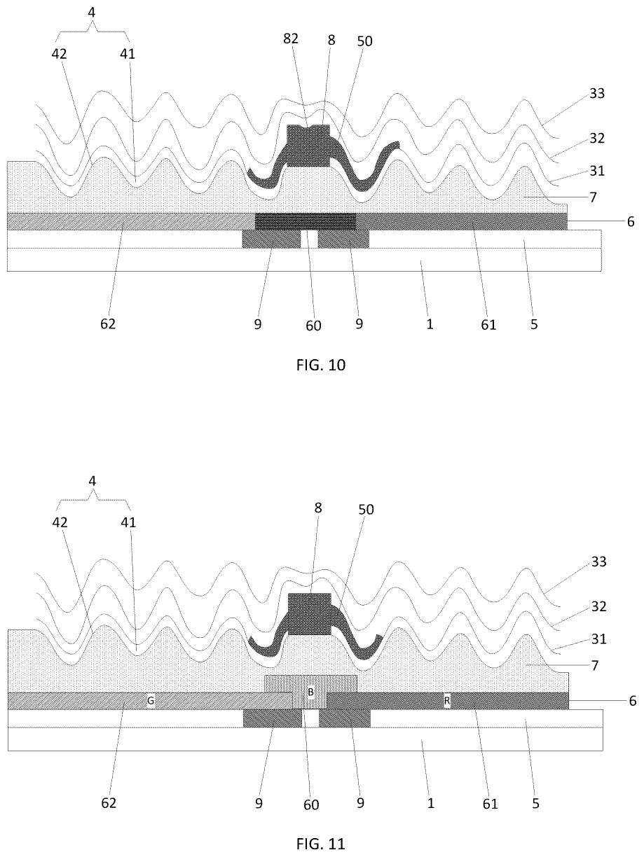

In some embodiments, the larger the area of the sub-filtering layer, the more light is emitted, and the larger the area of the region in which reflected light exists, and in order to ensure that reflected light corresponding to the sub-filtering layers with different areas is blocked, in the above-described display panel provided by embodiments of the present disclosure, as shown in FIG. 10, the area of the orthographic projection of the light-blocking structure 50 on the base substrate 1 may be directly proportional to the area of the sub-filtering layers (61, 62, 63). That is, the larger the area of the sub-filtering layer corresponding to the sub-pixel, the larger the area of the orthographic projection of the corresponding light-blocking structure 50. For example, the area of the red light sub-filtering layer 61>the area of the green light sub-filtering layer 62>the area of the blue light sub-filtering layer 63, such that the area of the light-blocking structure 50 corresponding to the red light sub-filtering layer 61>the area of the light-blocking structure 50 corresponding to the green light sub-filtering layer 62>the area of the light-blocking structure 50 corresponding to the blue light sub-filtering layer 63. It will be appreciated that in some embodiments, the area of the sub-filtering layer may be viewed as a light emitting area of the light-emitting device of the corresponding sub-pixel.

In some embodiments, as shown in FIG. 10, an overlapping area of the light-blocking structure 50 corresponding to the red light sub-filtering layer 61 and the metal wiring 9 is larger than an overlapping area of the light-blocking structure 50 corresponding to the green light sub-filtering layer 62 and the metal wiring 9, and such a design can ensure that the light-blocking structure 50 blocks the light that may be leaked from the sub-filtering layer with a larger area as far as possible.

In some embodiments, as shown in FIG. 10, at least one concavity structure 82 may be formed on the upper surface of the pixel definition layer 8 (e.g., a height of the concavity structure 82 is 1/10 to 1/30 of the height of the pixel definition layer 8), such that the light-emitting layer 32 and/or the cathode 33 form a concave-convex structure along with the shape on the upper surface of the pixel definition layer 8, but the magnitude(a height difference between the highest point of the convex structure and the lower point of the concavity structure) of the concave-convex structure here is smaller than the magnitude (i.e., a height difference between the highest point of the protrusion 42 to the lowest point of the indentation 41) of the light-emitting enhancement structure 4 of the effective light-emitting region (e.g., a region corresponding to the sub-filtering layer). Such a design, on the one hand, makes the surface morphology of the cathode 33 basically consistent, and facilitates the yield of the subsequent process; and on the other hand, it can ensure that the reflectivity of the cathode 33 is basically consistent at various places on its surface.

It should be noted that FIG. 10 only schematically illustrates that the area of the light-blocking structure 50 corresponding to the red light sub-filtering layer 61 is larger than the area of the light-blocking structure 50 corresponding to the green light sub-filtering layer 62.

In some embodiments, in the above-described display panel provided by embodiments of the present disclosure, as shown in FIG. 9 and FIG. 10, an anti-light crosstalk structure 60 is provided between every adjacent sub-filtering layers (e.g., 61 and 62), and orthographic projections of the anti-light crosstalk structure 60, the light-blocking structure 50 and the metal wiring 9 have a first overlapping region AA on the base substrate 1, and a width of the first overlapping region AA is greater than half of a width of the metal wiring 9. In this way, the light of the adjacent sub-pixels that may be reflected by the metal wiring 9 can be further absorbed.

In some embodiments, in the above-described display panel provided by embodiments of the present disclosure, a material of the anti-light crosstalk structure 60 may be a black matrix, as shown in FIG. 9 and FIG. 10. Exemplarily, the black matrix may be made of a black organic material, for example, chromium (Cr), chromium oxide (CrOx), black resin, or graphene may be used.

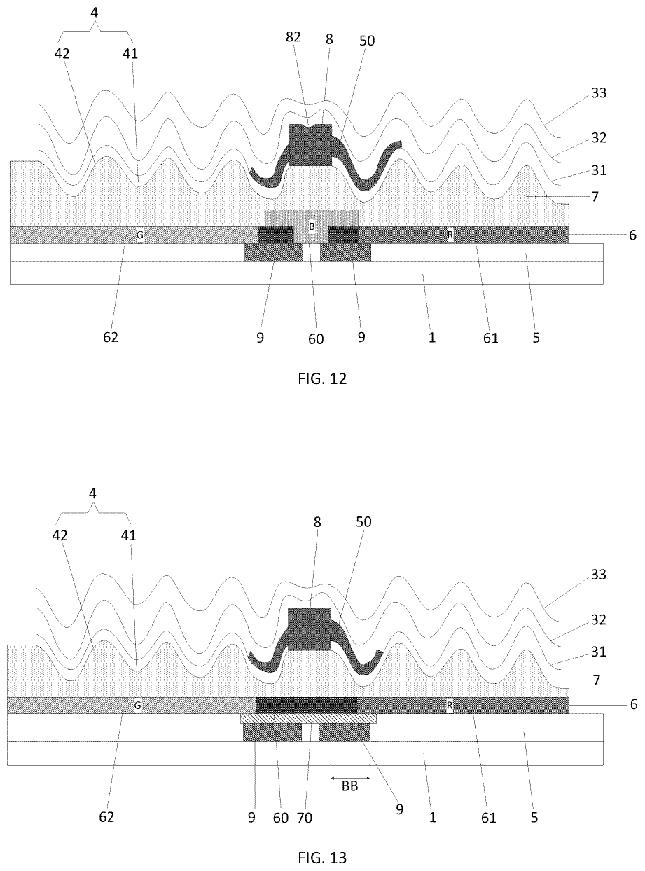

In some embodiments, in the above-described display panel provided by embodiments of the present disclosure, as shown in FIG. 11 and FIG. 12, the anti-light crosstalk structure 60 may be a filter structure (e.g., a blue light filter structure) having a different color from two sub-filtering layers (e.g., the red light sub-filtering layer 61 and the green light sub-filtering layer 62) adjacent to the anti-light crosstalk structure, and the light emitted from the two sub-filtering layers (e.g., the red light sub-filtering layer 61 and the green light sub-filtering layer 62) and the light (blue light) emitted from the anti-light crosstalk structure 60 are mixed as white light. For example, a portion of the light emitted from the red sub-pixel (R) passes through the anti-light crosstalk structure 60 (blue light filter structure) and is mixed into green light, and the green light enters the adjacent green light sub-filtering layer 62 without any light crosstalk problem. Optionally, an anti-light crosstalk structure 60 between the red light sub-filtering layer 61 and the green light sub-filtering layer 62 may be made of a blue light filtering material, an anti-light crosstalk structure 60 between the green light sub-filtering layer 62 and the blue light sub-filtering layer 63 may be made of a red light filtering material, and an anti-light crosstalk structure 60 between the red light sub-filtering layer 61 and the blue light sub-filtering layer 63 may be made of a green light filtering material.

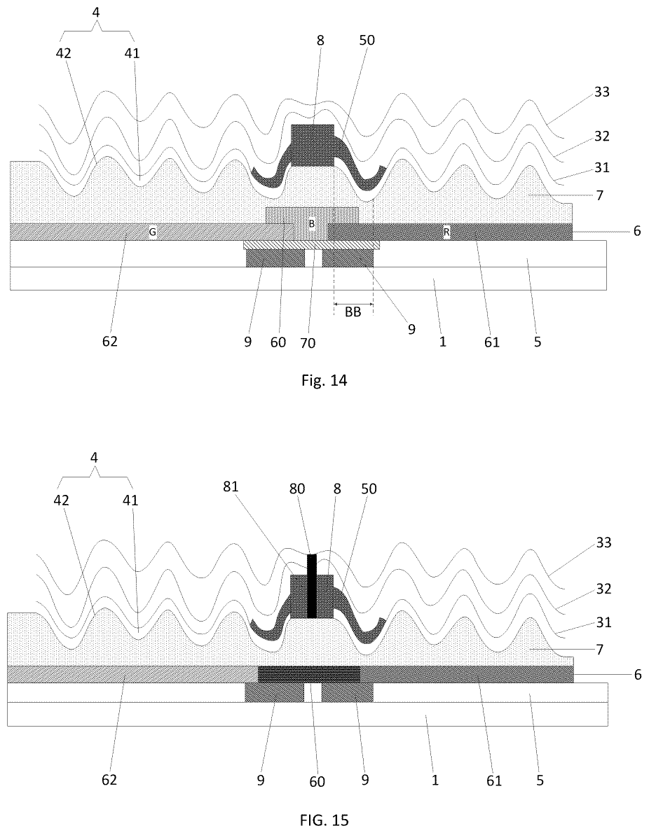

In some embodiments, as shown in FIG. 13 and FIG. 14, the above-described display panel provided by embodiments of the present disclosure further includes an anti-reflection layer 70 disposed between the metal wiring 9 and the passivation layer 5, and an orthographic projection of the metal wiring 9 on the base substrate 1 is located within an orthographic projection of the anti-reflection layer 70 on the base substrate 1. For example, a black organic resin or a black PDL material is used to fabricate the anti-reflection layer 70, which can further absorb light that may be reflected by the metal wiring 9 from adjacent sub-pixels.

In some embodiments, in the above-described display panel provided by embodiments of the present disclosure, as shown in FIG. 13 and FIG. 14, the orthographic projections of the anti-reflection layer 70, the light-blocking structure 50, and the metal wiring 9 on the base substrate 1 have a second overlapping region BB, a width of the second overlapping region BB is greater than half of a width of the metal wiring 9. As such, the light of adjacent sub-pixels that may be reflected by the metal wiring 9 can be further absorbed.

Optionally, anti-reflection layers 70 corresponding to respective metal wirings 9 may be independent of each other or may be a ring-like one-piece structure.

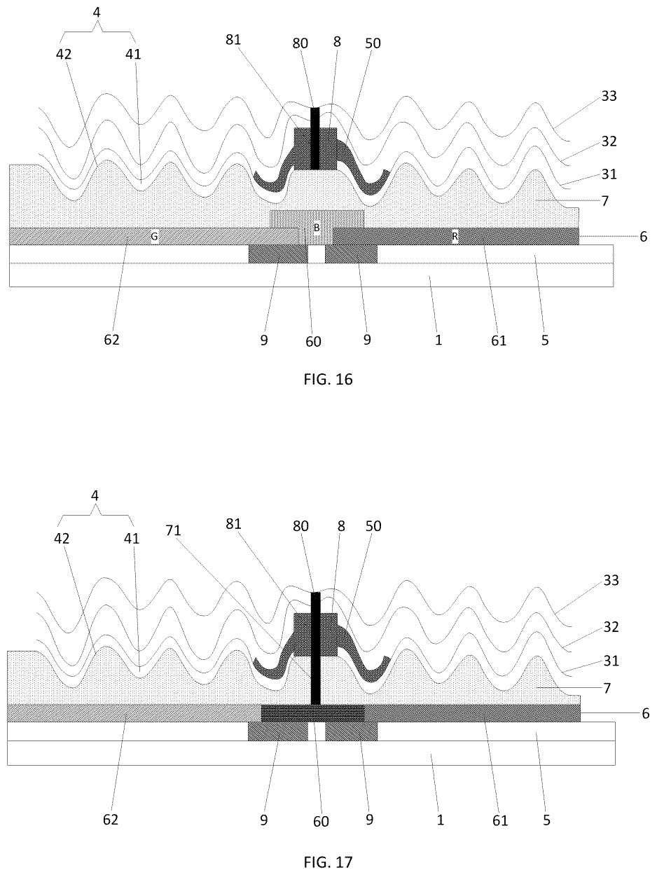

In some embodiments, in the above-described display panel provided by embodiments of the present disclosure, as shown in FIG. 15 and FIG. 16, the pixel definition layer 8 is provided a first groove 81, and the first groove 81 is filled with a light-absorbing structure 80. In this way, a groove is gouged within the pixel definition layer 8 of the adjacent sub-pixels and the light-absorbing structure 80 is filled in the groove, so that light of the adjacent sub-pixels that may be reflected by the metal wirings 9 can be further absorbed.

In some embodiments, in the above-described display panel provided by embodiments of the present disclosure, a depth of the first groove 81 may be less than or equal to the height of the pixel definition layer 8, as shown in FIG. 15 and FIG. 16. FIG. 15 and FIG. 16 of embodiments of the present disclosure are illustrated as an example where the depth of the first groove 81 is equal to the height of the pixel definition layer 8.

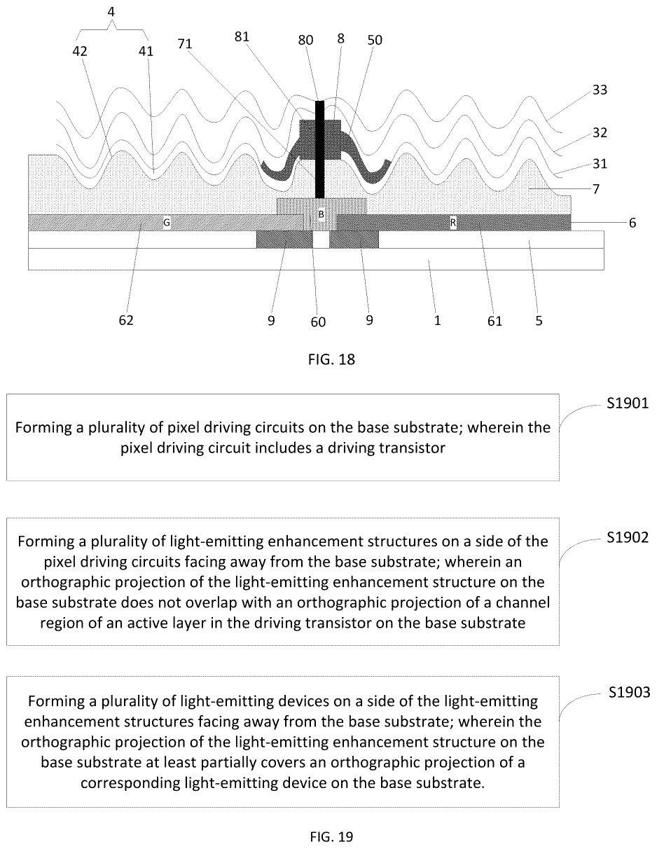

In a possible implementation, in the above-described display panel provided by embodiments of the present disclosure, as shown in FIG. 17 and FIG. 18, the planarization layer 7 is provided a second groove 71 arranged in correspondence with the first groove 81, the second groove 71 penetrates through the planarization layer 7, and the light-absorbing structure 80 extends into the second groove 71 and is in contact with the anti-light crosstalk structure 60. In this way, the light-absorbing structure 80 can provide a certain degree of support to the display panel and can further absorb the light that may be leaked from adjacent sub-pixels.

In some embodiments, in the above-described display panel provided by embodiments of the present disclosure, the material of the light-absorbing structure 80 may be a black organic resin, as shown in FIG. 15-FIG. 18.

In some embodiments, in the above-described display panel provided by embodiments of the present disclosure, as shown in FIG. 15-FIG. 18, the material of the light-absorbing structure 80 may be a ferrous metal, and a top part of the light-absorbing structure 80 facing away from the base substrate 1 is electrically connected with the cathode 33, so that the light-absorbing structure 80 may act as an auxiliary cathode for the purpose of lowering the resistance of the cathode 33 and thereby lowering the IR Drop. In some embodiments, in the present disclosure embodiments provided in the above-described display panel, as shown in FIG. 15-FIG. 18, an orthographic projection of the light-absorbing structure 80 on the base substrate 1 may be located within a range of an orthographic projection of a spacing between adjacent metal wirings 9 on the base substrate 1, and a width of the orthographic projection of the light-absorbing structure 80 on the base substrate 1 may be slightly smaller than a width of the spacing between the adjacent metal wirings 9, and this design may avoid the light-absorbing structure 80 from having an overlap region with the metal wirings 9, which in turn leads to unevenness.

Optionally, the light-emitting device may be an inorganic light-emitting diode, an organic light-emitting diode (OLED) manufactured using organic materials, a micro light-emitting diode (Micro LED) or a mini light-emitting diode (mini LED). Micro LEDs are ultra-small inorganic light-emitting elements of less than 100 micrometers in size that are self-emitting without a backlight or filter.

Based on the same inventive concept, the embodiments of the present disclosure further provide a display panel manufacturing method, for manufacturing the above-described display panel provided by the present disclosure embodiments, as shown in FIG. 19, and the manufacturing method may include following steps.

S1901, forming a plurality of pixel driving circuits on the base substrate; where the pixel driving circuit includes a driving transistor.

S1902, forming a plurality of light-emitting enhancement structures on a side of the pixel driving circuits facing away from the base substrate; where an orthographic projection of the light-emitting enhancement structure on the base substrate does not overlap with an orthographic projection of a channel region of an active layer in the driving transistor on the base substrate.

S1903, forming a plurality of light-emitting devices on a side of the light-emitting enhancement structures facing away from the base substrate; where the orthographic projection of the light-emitting enhancement structure on the base substrate at least partially covers an orthographic projection of a corresponding light-emitting device on the base substrate.

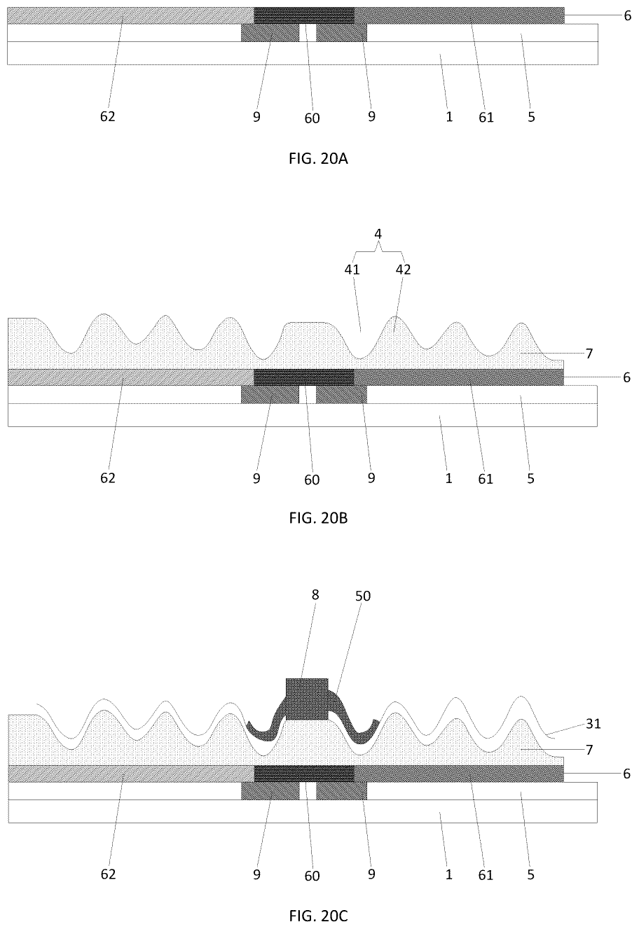

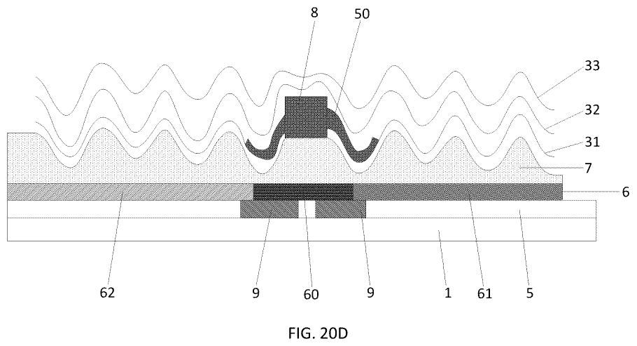

The following is a detailed description of the display panel manufacturing method provided by embodiments of the present disclosure, using the structure shown in FIG. 9 as an example.
(1) a light-shielding layer LS is formed on the base substrate 1, a buffer layer 10 is formed on the light-shielding layer LS, a pixel driving circuit such as the 3T1C structure shown in FIG. 4 is formed on the buffer layer 10, and forming the pixel driving circuit specifically includes forming an active layer Act, a gate insulating layer 20, a gate layer (G2, G), an interlayer insulating layer 30, and a source-drain metal layer (S2, D2, and a metal wiring 9); the materials, thicknesses, and manufacture methods of the above film layers may be the same as those of the prior art, and are not described in detail herein.
(2) A passivation layer 5 is formed on the source-drain metal layer, and a patterned anti-light crosstalk structure 60 is formed on the passivation layer 5, for example, the anti-light crosstalk structure 60 may be an annular structure, the anti-light crosstalk structure 60 has a plurality of openings, and a sub-filtering layer 6 including a red light sub-filtering layer 61, a green light sub-filtering layer 62, a blue light sub-filtering layer 63, and a white light sub-filtering layer 64 is formed within the openings, as shown in FIG. 20A.
(3) A resin layer is formed on the sub-filtering layer 6 by deposition, and a light-emitting enhancement structure 4 having an indentation 41 and a protrusion 42 is formed on the surface of the resin layer by an exposure development process, as shown in FIG. 20B.
(4) A patterned anode 31 is formed on the light-emitting enhancement structure 4, a pixel definition layer 8 and a light-blocking structure 50 arranged in contact with the inner wall of the pixel definition layer 8 are formed on the anode 31 by a single mask patterning process, and the pixel definition layer 8 have pixel openings corresponding to the red light sub-filtering layer 61, the green light sub-filtering layer 62, the blue light sub-filtering layer 63, and the white light sub-filtering layer 64, as shown in FIG. 20C.
(5) Light-emitting layers 32 are formed within the pixel openings, cathodes 33 are formed on the light-emitting layers 32, as shown in FIG. 20D.

Afterwards, an encapsulation layer may be formed above the cathodes using a thin film encapsulation.

It should be noted that the display panel manufacturing method described in FIG. 10-FIG. 18 is basically the same as the manufacturing method shown in FIG. 9, and the difference lies in the difference in the production area of the light-blocking structure 50 in different sub-pixels, the structure of the anti-light crosstalk structure 60, the structure of the pixel definition layer 8, the anti-reflection layer 70, and the light-absorbing structure 80, etc. The specific manufacturing steps of FIG. 10-FIG. 18 will not be described in detail herein.

Based on the same inventive conception, the embodiments of the present disclosure further provide a display apparatus including the above-described display panel provided by the embodiments of the present disclosure. The principle of the display apparatus solving the problem is similar to that of the above-mentioned display panel, thus, the implementation of the display apparatus may refer to the implementation of the above-mentioned display panel, and repetitions will be omitted.

In some embodiments, the above-described display apparatus provided by the embodiments of the present disclosure may be a full-screen display apparatus, or may also be a flexible display apparatus, etc., and is not limited herein.

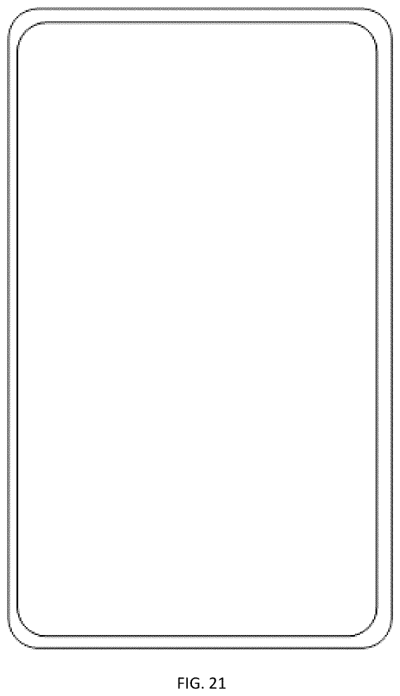

In some embodiments, the above-described display apparatus provided by the embodiments of the present disclosure may be a cell phone with a full screen as shown in FIG. 21. Of course, the above-described display apparatus provided by the embodiments of the present disclosure may also be a tablet computer, a television, a monitor, a laptop computer, a digital photo frame, a navigator, and any other product or component having a display function. Other essential components of the display apparatus should be understood by those of ordinary skill in the art, and are not described herein, nor should they be taken as limitations on the present disclosure.

Embodiments of the present disclosure provide a display panel, a display panel manufacturing method, and a display apparatus, the light emitting rate of the display panel can be improved by providing a light-emitting enhancement structure whose orthographic projection at least partially covers the light-emitting device; since the channel region of the active layer (e.g., a channel region of an oxide-type active layer) in a transistor (e.g., a driving transistor) is greatly affected by light, the light-emitting enhancement structure should be kept as far away from the channel region as possible. In the present disclosure, the orthographic projection of the light-emitting enhancement structure on the base substrate is set to not overlap with the orthographic projection of the channel region of the active layer of the transistor (e.g., driving transistor) on the base substrate, so that light irradiation to the channel region of the driving transistor can be avoided while improving the light emitting rate of the product, thereby ensuring that the channel region of the driving transistor is not affected by light, and improving the performance of the pixel driving circuit.

Although the preferred embodiments of the present disclosure have been described, those skilled in the art will be able to make additional changes and modifications to these embodiments once the basic inventive concepts are apparent. Therefore, it is intended that the appended claims be construed to include the preferred embodiments and all changes and modifications that fall within the scope of the present disclosure.

Obviously, those skilled in the art can make various changes and modifications to the embodiments of the present disclosure without departing from the spirit and scope of the embodiments of the present disclosure. In this way, if these modifications and variations of the embodiments of the present disclosure fall within the scope of the claims of the present disclosure and equivalent technologies, the present disclosure is also intended to include these modifications and variations.

1. A display panel, comprising:
a base substrate;
a plurality of pixel driving circuits on a side of the base substrate, wherein the pixel driving circuit comprises a driving transistor;
a plurality light-emitting devices on a side of the pixel driving circuits facing away from the base substrate, wherein the light-emitting device is electrically connected with a corresponding pixel driving circuit;
a plurality of light-emitting enhancement structures, between the pixel driving circuits and the light emitting devices, an orthographic projection of the light-emitting enhancement structure on the base substrate at least partially covers an orthographic projection of a corresponding light-emitting device on the base substrate, and the orthographic projection of the light-emitting enhancement structure on the base substrate does not overlap with an orthographic projection of a channel region of an active layer in the driving transistor on the base substrate.

2. The display panel according to claim 1, wherein a distance between adjacent boundaries of orthographic projections, on the base substrate, of the light-emitting enhancement structure and the channel region of the active layer in the driving transistor is directly proportional to an area of the light-emitting device.

3. The display panel according to claim 2, further comprising:
a passivation layer between the pixel driving circuits and the light-emitting devices,
a filtering layer between the passivation layer and the light-emitting devices,
a planarization layer between the filtering layer and the light-emitting devices,
a pixel definition layer on a side of the planarization layer facing away from the base substrate, and
a metal wiring between the base substrate and the passivation layer and electrically connected with the pixel driving circuits;
wherein the pixel definition layer defines a plurality of sub-pixels, the plurality of light-emitting devices are disposed correspondingly within the plurality of the sub-pixels, the filtering layer comprises a plurality of sub-filtering layers disposed correspondingly within the plurality of the sub-pixels, the planarization layer comprises the light-emitting enhancement structures, and an orthographic projection of the pixel definition layer on the base substrate at least covers an orthographic projection of a portion of the metal wiring on the base substrate.

4. The display panel according to claim 3, wherein,
the light-emitting enhancement structure comprises a plurality of indentations and a plurality of protrusions, and
tilt angles of the protrusions are inversely proportional to a wavelength of light emitted from a corresponding sub-pixel.

5. The display panel according to claim 4, wherein the tilt angles of the protrusions corresponding to the sub-pixels each is 30°~60°, and a difference in tilt angles of protrusions corresponding to every two adjacent sub-pixels, from which light with different wavelengths is emitted, is 5°~10°.

6. The display panel according to claim 3, wherein the light-emitting enhancement structure comprises a plurality of indentations and a plurality of protrusions, an area of orthographic projections of the protrusions on the base substrate is directly proportional to an area of the sub-filtering layer;
wherein a shape of the orthographic projection of the protrusion on the base substrate is hexagonal, pentagonal or triangular.

7. (canceled)

8. The display panel according to claim 4, wherein an included angle between a central axis of orthographic projections of the protrusions on the base substrate and a vertical direction is directly proportional to a wavelength of light emitted from the corresponding sub-pixel.

9. The display panel according to claim 8, wherein the included angle corresponding to each of the sub-pixels is 3° to 18°, and a difference in included angles corresponding to every two adjacent sub-pixels, from which light with different wavelengths is emitted, is 3° to 5°.

10. The display panel according to claim 4, wherein at least one side, along an arrangement direction of the sub-pixels, of at least one light-emitting enhancement structure corresponding to a sub-pixel is provided with a vacant portion; wherein an area of the vacant portion is directly proportional to an area of the sub-filtering layer.

11. (canceled)

12. The display panel according to claim 4, wherein the light-emitting device comprises: an anode between the planarization layer and the pixel definition layer, a light emitting layer on a side of the anode facing away from the base substrate, and a cathode on a side of the light emitting layer facing away from the base substrate; and
each of the sub-pixels further comprises a light-blocking structure between the anode and the light emitting layer, wherein the light-blocking structure is arranged in contact with an inner wall of the pixel definition layer, an orthographic projection of the light-blocking structure on the base substrate at least covers an orthographic projection of a portion of the light-emitting enhancement structure on the base substrate.

13. The display panel according to claim 12, wherein, a structure of the light-emitting enhancement structure adjacent to the inner wall of the pixel definition layer is the indentation, and
the orthographic projection of the light-blocking structure on the base substrate covers at least an orthographic projection of the lowest point of the indentation adjacent to the inner wall of the pixel definition layer on the base substrate:
wherein the orthographic projection of the light-blocking structure on the base substrate at least covers an orthographic projection of half a width of the metal wiring on the base substrate.

14. (canceled)

15. The display panel according to claim 12, wherein the light-blocking structure is arranged in a same layer and made of a same material as the pixel definition layer;
wherein a material of the pixel definition layer is a black light-absorbing material.

16. (canceled)

17. The display panel according to claim 12, wherein an area of the orthographic projection of the light-blocking structure on the base substrate is directly proportional to an area of the sub-filtering layer.

18. The display panel according to claim 12, wherein an anti-light crosstalk structure is provided between every adjacent sub-filtering layers, orthographic projections of the anti-light crosstalk structure, the light-blocking structure and the metal wiring on the base substrate have a first overlapping region, and a width of the first overlapping region is greater than half a width of the metal wiring;
wherein a material of the anti-light crosstalk structure is a black matrix.

19. (canceled)

20. The display panel according to claim 18, wherein the anti-light crosstalk structure is a filter structure that is different in color from two sub-filtering layers adjacent to the anti-light crosstalk structure, and light emitted from the two sub-filtering layers and light emitted from the anti-light crosstalk structure are mixed as white light.

21. The display panel according to claim 12, further comprising an anti-reflection layer between the metal wiring and the passivation layer;
wherein an orthographic projection of the metal wiring on the base substrate is within an orthographic projection of the anti-reflection layer on the base substrate;
wherein orthographic projections of the anti-reflection layer, the light-blocking structure and the metal wiring on the base substrate have a second overlapping region, and a width of the second overlapping region is greater than half a width of the metal wiring.

22. (canceled)

23. The display panel according to claim 3, wherein the pixel definition layer is provided with a first groove, and the first groove is filled with a light-absorbing structure;
wherein a depth of the first groove is less than or equal to a height of the pixel definition layer;
wherein, a material of the light-absorbing structure is a black organic resin; or, a material of the light-absorbing structure is a ferrous metal, and a top part of the light-absorbing structure facing away from the base substrate is electrically connected with the cathode.

24. (canceled)

25. The display panel according to claim 23, wherein the planarization layer is provided with a second groove arranged in correspondence with the first groove, the second groove penetrates through the planarization layer, and the light-absorbing structure extends into the second groove and is in contact with the anti-light crosstalk structure.

26. (canceled)

27. (canceled)

28. A display apparatus, comprising the display panel according to claim 1.

29. A display panel manufacturing method, wherein the manufacturing method comprises:
forming a plurality of pixel driving circuits on a base substrate; wherein the pixel driving circuit comprises a driving transistor;
forming a plurality of light-emitting enhancement structures on a side of the pixel driving circuits facing away from the base substrate; wherein an orthographic projection of the light-emitting enhancement structure on the base substrate does not overlap with an orthographic projection of a channel region of an active layer in a driving transistor on the base substrate;
forming a plurality of light-emitting devices on a side of the light-emitting enhancement structures facing away from the base substrate; wherein the light-emitting device is electrically connected with a corresponding pixel driving circuit, and the orthographic projection of the light-emitting enhancement structure on the base substrate at least partially covers an orthographic projection of a corresponding light-emitting device on the base substrate.
